(19) United States
(12) Patent Application Publication
(10) Pub. No.: US 2025/0174593 A1
(43) Pub. Date: May 29, 2025

(54) SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventor: Satoshi HATTORI, Ibo Hyogo (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 18/905,364

(22) Filed: Oct. 3, 2024

(30) Foreign Application Priority Data
Nov. 24, 2023 (JP) 2023-198843

(51) Int. Cl. H01L 23/00; H01L 23/31; H01L 23/498

(52) U.S. Cl. CPC H01L 24/32; H01L 23/3107; H01L 23/49844; H01L 23/49866; H01L 24/29; H01L 2224/29111; H01L 2224/29113; H01L 2224/29116; H01L 2224/29118; H01L 2224/2912; H01L 2224/29144; H01L 2224/29147; H01L 2224/29155; H01L 2224/32245; H01L 2924/3656

(57) ABSTRACT

A semiconductor device according to an embodiment includes: a first conductive member; a first conductive film provided on a part of the first conductive member and including a metal element that is smaller in diffusion coefficient than the first conductive member; a first solder material provided on the first conductive film; a semiconductor element provided on the first solder material; a second solder material provided on the semiconductor element; a second conductive member including a first region facing the semiconductor element via the second solder material; a resin sealing the first conductive member, the second conductive member, the first conductive film, the first solder material, the second solder material, and the semiconductor element; and a first peripheral region of the first conductive member that is in direct contact with the resin and is located around a region where the semiconductor element overlaps.

### CROSS-REFERENCE TO RELATED APPLICATION

This application is based upon and claims the benefit of priority from Japanese Patent Application No. 2023-198843, filed Nov. 24, 2023, the entire contents of which are incorporated herein by reference.

### FIELD

Embodiments of the present invention relate generally to a semiconductor device.

### BACKGROUND

A semiconductor element and a conductive member such as a die pad may be joined using a solder. For example, when a solder includes a metal containing Sn and a die pad includes a metal containing Cu, there is a risk of generation of a Kirkendall void in the die pad due to mutual diffusion between the different metal elements.

### DESCRIPTION OF THE DRAWINGS

FIG. 1 is a perspective view illustrating semiconductor device 101 according to a first embodiment.

FIG. 2 is a perspective view illustrating an internal wiring structure of the semiconductor device 101 according to the first embodiment.

FIG. 3 is a cross-sectional view taken along line A-A′ illustrated in FIG. 2.

FIG. 4A is a top view illustrating a positional relationship between a first conductive film 21 and a first solder material 31.

FIG. 4B is a top view illustrating a positional relationship between the first conductive film 21 and the first solder material 31.

FIG. 4C is a top view illustrating a positional relationship between the first conductive film 21 and the first solder material 31.

FIG. 5 is a cross-sectional view illustrating a semiconductor device 102 according to a second embodiment.

FIG. 6 is a top view illustrating a positional relationship between the first conductive film 21 and the first solder material 31.

FIG. 7 is a cross-sectional view illustrating a semiconductor device 103 according to a third embodiment.

FIG. 8 is a cross-sectional view illustrating a semiconductor device 104 according to a fourth embodiment.

FIG. 9 is a cross-sectional view illustrating a semiconductor device 105 according to a fifth embodiment.

### DETAILED DESCRIPTION

Embodiments of the present invention will now be described herein with reference to the accompanying drawings.

A semiconductor device according to an embodiment includes: a first conductive member; a first conductive film provided on a part of the first conductive member and including a metal element that is smaller in diffusion coefficient than the first conductive member; a first solder material provided on the first conductive film; a semiconductor element provided on the first solder material; a second solder material provided on the semiconductor element; a second conductive member including a first region facing the semiconductor element via the second solder material; a resin sealing the first conductive member, the second conductive member, the first conductive film, the first solder material, the second solder material, and the semiconductor element; and a first peripheral region of the first conductive member that is in contact with the resin and is located around a region where the semiconductor element overlaps.

Note that the drawings are schematic or conceptual. A relationship between a thickness and a width of each portion, and a ratio of sizes between the portions, for example, may not be necessarily identical to those of actual portions. In addition, even in a case of illustrating an identical portion, dimensions and ratios may be illustrated in a different manner from each other among the drawings.

For example, some are illustrated with a laminated structure in the cross-sectional views described in the specification of the present application. However, a ratio of thicknesses of layers in the laminated structure may not be necessarily identical to those of actual layers. Even in a case where one layer is illustrated thicker than another layer in each of the cross-sectional views, the thicknesses of the one layer and the other layer may be substantially identical to each other or the one layer may be thinner than the other layer in reality. That is, dimensions such as thicknesses indicated in the drawings in the specification of the present application may be different from actual dimensions.

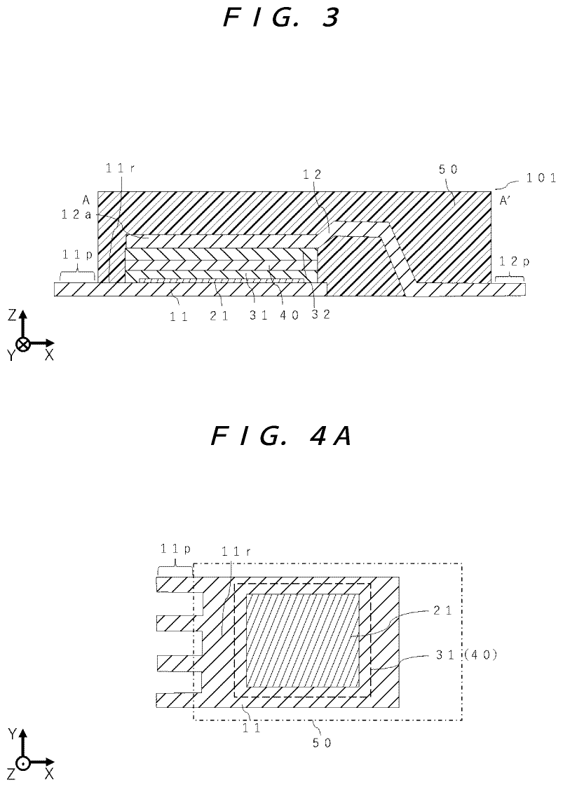

A direction heading from a first conductive member 11 toward a semiconductor element 40 is defined as a Z direction (a first direction). In addition, a direction orthogonal to the Z direction is defined as an X direction (a second direction), and a direction intersecting the X direction and the Z direction is defined as a Y direction (a third direction). A semiconductor device 101 illustrated in FIG. 3 is illustrated in a cross-sectional view on an X-Z plane.

Note that the X direction, the Y direction, and the Z direction, which are illustrated to be in an orthogonal relationship in the present embodiment, are not limited to be in the orthogonal relationship, and may be in a relationship where the directions intersect each other.

In addition, for purposes of explanation, a positive direction of the Z direction is referred to as “upper”, and a negative direction of the Z direction is referred to as “lower”. However, the “upper” and “lower” directions are not limited to gravity directions or directions when the semiconductor device is mounted.

Note that, in the specification of the present application and each of the drawings, identical elements to those described previously with respect to the drawings described previously are denoted by an identical reference numeral, and its detailed description is appropriately omitted.

### First Embodiment

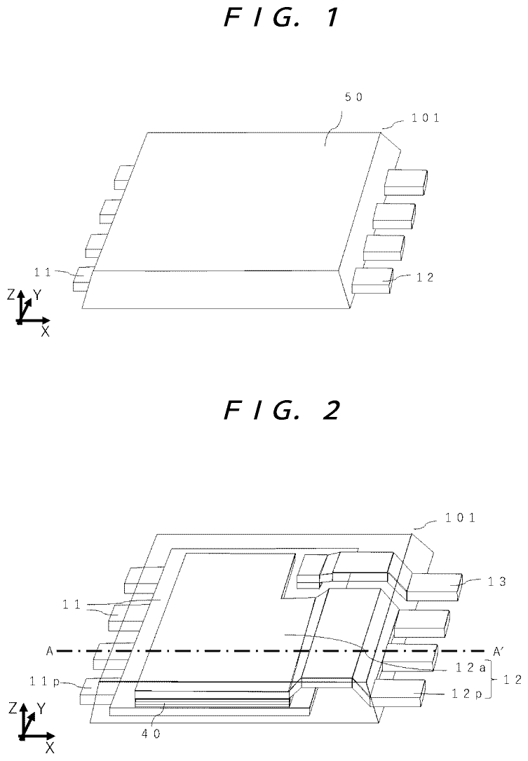

FIGS. 1 and 2 are perspective views each illustrating a semiconductor device 101 according to a first embodiment. FIG. 1 illustrates an appearance including a resin 50. FIG. 2 illustrates an example of an internal wiring structure. As illustrated in FIG. 1, parts of a first conductive member 11 and a second conductive member 12 that the semiconductor device 101 includes protrude from the resin 50. The first conductive member 11 is, for example, a lead frame. A plurality of the parts of each of the first conductive member 11 and the second conductive member 12 may be exposed from the resin 50. Note that a case where a part is exposed includes a case where a part is protruded as illustrated in FIGS. 1 and 2 and a case where a part is exposed on a lower surface of a package.

FIG. 2 illustrates the internal wiring structure sealed by the resin 50 illustrated in FIG. 1. A semiconductor element 40 is provided between the first conductive member 11 and the second conductive member 12. In the second conductive member 12, a region to which the semiconductor element 40 faces in the Z direction is referred to as a first region 12a. The semiconductor element 40 is sealed by the resin 50. The first conductive member 11 and the second conductive member 12 are each electrically coupled to the semiconductor element 40. A part of the first conductive member 11 and a part of the second conductive member 12 are sealed by the resin 50.

For example, a metal-oxide semiconductor field-effect transistor (MOSFET) is formed in the semiconductor element 40. The first conductive member 11 is coupled to, for example, a drain electrode of the semiconductor element 40, and the second conductive member 12 is coupled to, for example, a source electrode. In addition, the semiconductor device 101 may further include a third conductive member 13. The third conductive member 13 is electrically coupled to, for example, a gate electrode of the MOSFET. The third conductive member 13 is not limited to a plate-shaped member illustrated in FIG. 2. The third conductive member 13 may include, for example, a bonding wire.

The first conductive member 11 includes first protrusions 11p each protruding from the resin 50. The first protrusions 11p, which are provided at four locations in FIG. 2, may not necessarily be provided at four locations. In addition, the second conductive member 12 includes second protrusions 12p each protruding from the resin 50. The second protrusions 12p, which are provided at three locations in FIG. 2, may not necessarily be provided at three locations.

Shapes of the first protrusions 11p and the second protrusions 12p are not limited to shapes illustrated in FIG. 2. For example, the shapes may each be a gull-wing shape or a J-letter shape. The gull-wing shape is a shape having a step where there are different positions in the Z direction. A step is provided in the negative direction of the Z direction toward a tip of each of the first protrusions 11p or the second protrusions 12p. The J-letter shape is, for example, a shape in which each of the first protrusions 11p is bent in the X-Z plane and the tip of each of the first protrusions 11p is directed in the positive direction in the X direction. In addition, the first protrusions 11p and the second protrusions 12p do not need to protrude from the resin 50 in the X direction, and may allow external electrical coupling on a lower surface of the resin 50.

FIG. 3 illustrates a cross section taken along line A-A′ illustrated in FIG. 2. The A-A′ cross section is a cross section passing through one of the first protrusions 11p of the first conductive member 11 and one of the second protrusions 12p of the second conductive member 12 illustrated in FIG. 2.

A first conductive film 21, a first solder material 31, the semiconductor element 40, and a second solder material 32 are provided between the first conductive member 11 and the second conductive member 12. The first conductive film 21 is provided on a part of the first conductive member 11. The first solder material 31 is provided on the first conductive film 21 and is in contact with a part of the first conductive member 11 and at least a part of the first conductive film 21. The semiconductor element 40 is provided on the first solder material 31.

The first conductive film 21 is not provided on the first protrusions 11p of the first conductive member 11. The first conductive film 21 that is covered with the first solder material 31 and is not in contact with the resin 50 is desirable for making it possible to improve a degree of adhesion of the resin 50 as will be described later.

The second conductive member 12 includes the first region 12a to which the semiconductor element 40 faces in the Z direction. The second solder material 32 is provided between the semiconductor element 40 and the first region 12a of the second conductive member 12. The first region 12a and the semiconductor element 40 face each other via the second solder material 32, and are electrically coupled to each other.

The first conductive member 11 and the second conductive member 12 include, for example, metals containing Cu. The first conductive member 11 and the second conductive member 12 may each include an identical material.

The first conductive film 21 includes, for example, a metal containing Ni. The first conductive film 21 functions as a barrier metal on a joint surface between the first conductive member 11 and the first solder material 31. The first conductive film 21 includes a metal element that is smaller in diffusion coefficient than the first conductive member 11. Note herein that a smaller diffusion coefficient refers to a less likelihood that metal atoms rarely move on a joint surface between metals that are different in type from each other. In other words, the diffusion coefficient quantifies the ease with which atoms migrate (i.e. atomic mobility).

The first solder material 31 and the second solder material 32 include, for example, solders containing Sn. The first solder material 31 and the second solder material 32 each include, for example, an identical material. The first solder material 31 and the second solder material 32 may contain Sn at, for example, a mass percent concentration of 50% or more. The first solder material 31 may contain at least Pb, Sb, Ni, Ag, Bi, Cu, or Zn, in addition to Sn.

The resin 50 seals the first conductive film 21, the first solder material 31, the semiconductor element 40, the second solder material 32, a part of the first conductive member 11, and a part of the second conductive member 12. The resin 50 includes, for example, an epoxy resin.

The first t conductive member 11 includes a first peripheral region 11r that is located around a region where the semiconductor element 40 overlaps. Note herein that the region where the semiconductor element 40 overlaps refers to a region where a shadow of the semiconductor element 40 extends in the first conductive member 11 when the semiconductor element 40 is projected in one direction (for example, the Z direction). As will be described with reference to FIG. 3, the first peripheral region 11r is a part of an upper surface of the first conductive member 11, and is located to surround a region where the first conductive member 11 and the first solder material 31 or the first conductive film 21 are in contact with each other. The first conductive member 11 is in direct contact with the resin 50 in at least a part of the first peripheral region 11r.

The first protrusions 11p and the second protrusions 12p are exposed from the resin 50. The first protrusions 11p and the second protrusions 12p are provided for electrical coupling to external electrodes. For example, as a voltage is applied between one of the first protrusions 11p and one of the second protrusions 12p, it is possible to allow a current to flow from the first conductive member 11 to the second conductive member 12 through the semiconductor element 40.

The first peripheral region 11r does not include the first protrusions 11p exposed from the resin 50.

The cross-sectional view of the semiconductor device 101 according to the first embodiment has been described above with reference to FIG. 3.

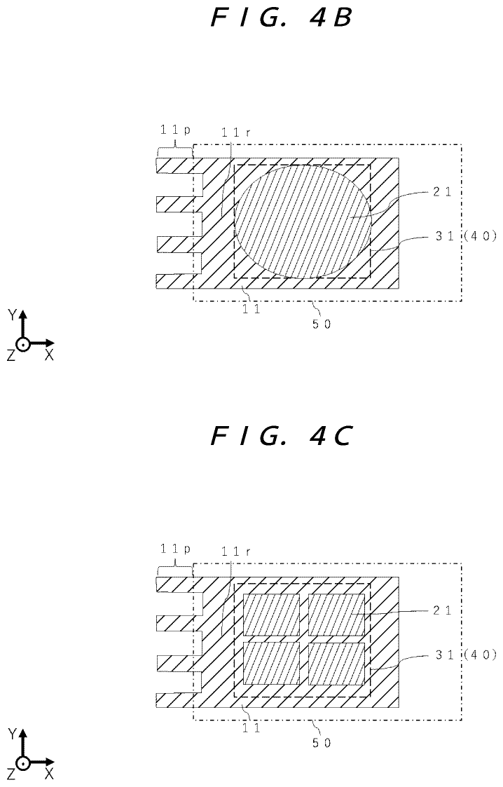

Next, examples of positional relationships between the first conductive film 21 and the first solder material 31 in the semiconductor device 101 according to the first embodiment will now be described herein with reference to FIGS. 4A to 4C. FIGS. 4A, 4B, and 4C are X-Y plan views illustrating the first conductive member 11 and the first conductive film 21.

In FIGS. 4A to 4C, the resin 50 is located in a region surrounded by an alternate long and short dash line. In addition, the first solder material 31 is located in a region surrounded by a dotted line. Hatching of the resin 50 and the first solder material 31 is omitted.

The first protrusions 11p are exposed from the resin 50. FIGS. 4A to 4C illustrate the examples in which the four first protrusions 11p are provided. However, the present invention is not limited to the examples. Note that the first solder material 31 and the semiconductor element 40 on the first solder material 31 may have outer shapes identical to each other, for example. That is, it is possible to regard the region surrounded by the dotted line as a region where the first solder material 31 is located, or it may be possible to regard the region as a region where the semiconductor element 40 is located.

The first peripheral region 11r of the first conductive member 11 is a region that is located around the region where the semiconductor element 40 overlaps. The first peripheral region 11r is located around the semiconductor element 40 in the positive direction and a negative direction of the X direction and in positive and negative directions of the Y direction. In FIGS. 4A to 4C, the first peripheral region 11r is indicated as a region outside the region that is indicated by the dotted line (the region where the semiconductor element 40 is provided) in the first conductive member 11, and that does not include the first protrusions 11p.

Note that it is possible to determine a shape of the first conductive film 21 based on an arrangement of the electrodes of the semiconductor element 40 provided on the first solder material 31. For example, determining the arrangement for allowing the first conductive film 21 to be present at a position overlapping with the electrodes when viewed in the Z direction desirably makes it possible to suppress generation of a Kirkendall void in a part where a current mainly flows.

Description will first be made with reference to FIG. 4A. The first conductive film 21 is covered with the first solder material 31 in the X-Y plane. Therefore, the resin 50 is not in contact with the first conductive film 21. At least the first solder material 31 is interposed between the resin 50 and the first conductive film 21. In other words, an outer shape of the first conductive film 21 in the X-Y plane is smaller than an outer shape of the first solder material 31 (the semiconductor element 40). In this case, a part of the first solder material 31 is in direct contact with the first conductive member 11.

In the example illustrated in FIG. 4A, the first conductive film 21 is not in direct contact with the resin 50. The first peripheral region 11r is in direct contact with the resin 50. In particular, a region that is located in the vicinity of the first protrusions 11p in the first peripheral region 11r is in direct contact with the resin 50. In other words, the first peripheral region 11r that is in contact with the resin 50 is located between the first conductive film 21 and the first protrusions 11p.

FIG. 4B illustrates a case where the shape of the first conductive film 21 is not square and have no corners. With a shape having a corner, there is a risk that stress concentrates at a portion having a large curvature (a small radius of curvature) in an interface between the first conductive film 21 and the first solder material 31. It is possible to alleviate such stress by providing, for example, the first conductive film 21 in an oval or elliptical shape having no corners.

In addition, as illustrated in FIG. 4C, the first conductive film 21 may be divided into a plurality of portions. FIG. 4C illustrates a case of division into two columns in both the X direction and the Y direction. However, further-fine division may be made. Otherwise division may be made into portions that are different in number in the X direction and the Y direction.

In FIGS. 4A, 4B, and 4C, an area of a region where the first conductive film 21 is provided may range, for example, from 20 to 90% of an area of a region where the first solder material 31 is provided (the region surrounded by the dotted line). In addition, the area may range from 30 to 80%.

With the semiconductor device 101 according to the present embodiment, where the first conductive film 21 is provided on a part of the first conductive member 11, and is interposed between the first conductive member 11 and the first solder material 31, it is possible to suppress generation of a Kirkendall void in the first conductive member 11 and to suppress deterioration of characteristics of the semiconductor device. Furthermore, it is possible to allow the first conductive member 11 to be in close contact with the resin 50 in the first peripheral region 11r, improving a degree of adhesion of the resin 50 and improving reliability of the semiconductor device.

With the semiconductor device 101 according to the present embodiment, it is possible to suppress generation of a Kirkendall void. An example in which the first conductive member 11 contains Cu, the first conductive film 21 contains Ni, and the first solder material 31 contains Sn will now be described herein for purposes of explanation.

It will be first considered a case where the first conductive film 21 is not provided. That is, the first conductive member 11 containing Cu and the first solder material 31 containing Sn are in contact with each other. At an interface where a metal containing Cu and a metal containing Sn are joined, an alloy containing Cu and Sn is formed. Atoms of Cu and atoms of Sn diffuse at rates different from each other at the interface. Progress of diffusion of the atoms of Cu is faster than that of the atoms of Sn (with a large diffusion coefficient). As a result, an amount of the atoms of Cu diffused from the first conductive member 11 toward the first solder material 31 is larger than an amount of the atoms of Sn diffused in an opposite direction. As described above, an effect of mutual diffusion at an interface where different metals are joined is referred to as a Kirkendall effect.

Due to a difference in diffusion coefficient between Cu and Sn, the atoms of Cu disappear from a region of the alloy generated in the first conductive member 11 containing Cu or the interface, generating a void. The void generated due to the Kirkendall effect is called a Kirkendall void.

That is, when the first conductive member 11 containing Cu and the first solder material 31 containing Sn are in contact with each other, a Kirkendall void may be generated in the first conductive member 11. When a Kirkendall void is generated, conductivity of the first conductive member 11 is deteriorated. There is thus a risk of an increase in on-voltage for the semiconductor element 40.

On the other hand, it will be considered a case where the first conductive film 21 containing Ni is provided, similar to the semiconductor device 101 according to the present embodiment. The diffusion coefficient of Ni is smaller than that of Cu. Therefore, the first conductive film 21 containing Ni makes it possible to suppress diffusion of the atoms from the first conductive member 11 to the first solder material 31. It is thus possible to suppress a Kirkendall void in the first conductive member 11.

Providing the first conductive film 21 in at least a part between the first conductive member 11 and the first solder material 31 makes it possible to suppress a Kirkendall void, suppressing deterioration of characteristics of the semiconductor device.

Furthermore, with the semiconductor device 101 according to the present embodiment, it is possible to improve a degree of adhesion of the resin 50. An example in which the first conductive member 11 contains Cu and the first conductive film 21 contains Ni will now be described herein for purposes of explanation. The resin 50 includes, for example, an epoxy resin. It is known that a degree of adhesion between Cu and an epoxy resin is superior than a degree of adhesion between Ni and the epoxy resin.

When the first conductive film 21 is formed wholly on the upper surface of the first conductive member 11, and is also provided in the first peripheral region and the first protrusions 11p, unlike the present embodiment, a degree of adhesion of the resin 50 is reduced. One reason for this is that the first conductive film 21 is also formed on the first peripheral region 11r, and the first conductive film 21 and the resin 50 are in direct contact with each other. Since the first conductive film 21 containing Ni presents a lower degree of adhesion to the resin 50 containing an epoxy resin than that of the first conductive member 11 containing Cu, there may be an increased risk of resin peeling, lowering reliability of the semiconductor device.

There is a risk that peeling (a crack) generated between the first conductive film 21 on the first peripheral region 11r and the resin 50 reaches the first solder material 31 or the semiconductor element 40 from an area in the vicinity of the first protrusions 11p. As moisture, for example, enters inside from outside through the crack, there is a risk that performance of the semiconductor device is deteriorated. When the first conductive film 21 is provided wholly on the upper surface of the first conductive member 11, as described above, there is a risk that a crack is generated in the resin 50, impairing reliability of the semiconductor device.

According to the present embodiment, on the other hand, by not providing the first conductive film 21 at least in the vicinity of the first protrusions 11p in the first peripheral region 11r, as illustrated in FIG. 3, the first conductive member 11 is in contact with the resin 50 in at least a part of the first peripheral region 11r. Since the degree of adhesion of t the first conductive 11 member containing Cu to the resin 50 is greater than that of the first conductive film 21 containing Ni, there is a small risk of resin peeling in the first peripheral region 11r.

As illustrated in FIG. 4A, the first conductive film 21 is covered with, for example, the first solder material 31. In other words, the first conductive film 21 is not in contact with the resin 50. By covering the first conductive film 21 with the first solder material 31, it is possible to suppress a decreased degree of adhesion due to when the first conductive film 21 and the resin 50 are in contact with each other. To increase a degree of adhesion of the resin 50, it is desirable that the first conductive film 21 be covered with the first solder material 31.

With the semiconductor device 101 according to the present embodiment, the resin 50 and the first conductive member 11 are in contact with each other in the first peripheral region 11r, suppressing resin peeling in the first peripheral region 11r and improving reliability of the semiconductor device. To increase a degree of adhesion of the resin 50, it is desirable that the first conductive film 21 be covered with the first solder material 31.

Note that, when the first conductive film 21 is covered with the first solder material 31, it is possible to more securely improve a degree of adhesion of the resin 50. Even if positional deviation occurs when the first solder material 31 and the semiconductor element 40 are provided, in a case where the first conductive film 21 is formed as illustrated in FIG. 4A, for example, the first conductive film 21 does not protrude from the first solder material 31 as long as a degree of the positional deviation is equal to or less than a predetermined magnitude. If positional deviation occurs, in a case where the first conductive film 21 that is identical in outer shape size to the first conductive member 11 or the semiconductor element 40 is formed, there is a risk that the first conductive film 21 protrudes from the first solder material 31.

With the semiconductor device 101 according to the present embodiment, forming the first conductive film 21 in at least a part between the first conductive member 11 and the first solder material 31 makes it possible to suppress a Kirkendall void, suppressing deterioration of characteristics of the semiconductor device. In addition, by not forming the first conductive film 21 in at least a part of the first peripheral region 11r, it is also possible to suppress peeling of the resin 50, improving reliability of the semiconductor device.

### Second Embodiment

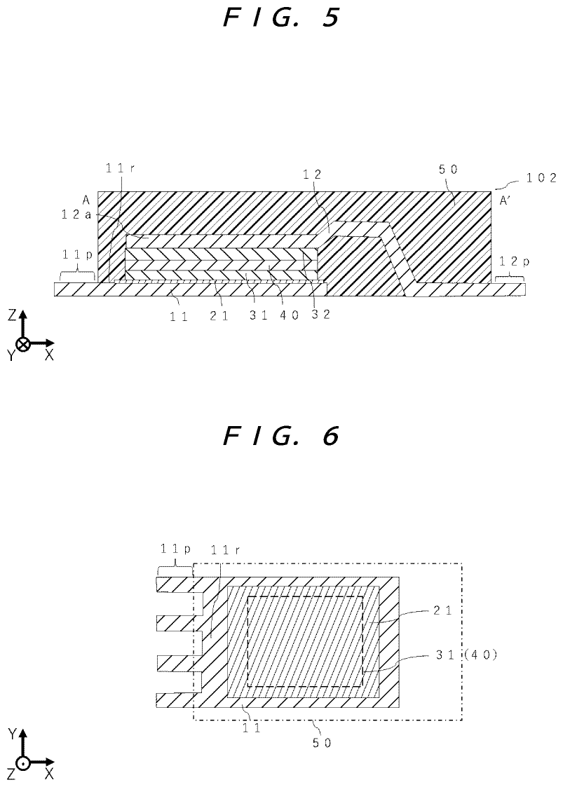

FIG. 5 is an A-A′ cross-sectional view of semiconductor device 102 according to a second embodiment. When an A-A′ cross-sectional view is referred to, in each embodiment, it is intended to be a cross-sectional view taken at a position corresponding to line A-A′ illustrated in FIG. 2 according to the first embodiment. FIG. 6 is a plan view illustrating an arrangement of the first conductive film 21, in the second embodiment. Part of description, which is common to the semiconductor device 101 according to the first embodiment, will be omitted.

A cross-sectional structure will first be described with reference to FIG. 5. As illustrated in FIG. 5, the first conductive film 21 is provided on a part of the first conductive member 11. The first solder material 31 is provided on the first conductive film 21. The first conductive film 21 is provided between the first solder material 31 and the first conductive member 11. The first solder material 31 and the first conductive member 11 are not in direct contact with each other.

A part of the first conductive film 21 is in contact with the resin 50. At least part of the first peripheral region 11r of the first conductive member 11 is in direct contact with the resin 50. The first conductive film 21 protruding from the first solder material 31 is provided in a part of the first peripheral region 11r. In the part of the first peripheral region 11r, the first conductive member 11 and the resin 50 face each other via the first conductive film 21.

On the other hand, the first conductive film 21 is not provided in the vicinity of the first protrusions 11p in the first peripheral region 11r. In other words, the first protrusions 11p and the first conductive film 2 are separated from each other. The first peripheral region 11r that is in contact with the resin 50 is provided between the first protrusions 11p and the first conductive film 21.

Next, a positional relationship between the first conductive film 21 and the first solder material 31 will now be described herein with reference to FIG. 6. A configuration illustrated in FIG. 6 is common to the configurations illustrated in FIGS. 4A, 4B, and 4C except for the shape of the first conductive film 21. For example, in FIG. 6, the resin 50 is located in a region surrounded by an alternate long and short dash line. The first solder material 31 is located in a region surrounded by a dotted line. In addition, it is understood that the region surrounded by the dotted line indicates the semiconductor element 40 provided on the first solder material 31. Hatching of the resin 50 and the first solder material 31 is omitted.

The first solder material 31 is formed on the first conductive film 21. An area where the first solder material 31 is provided is smaller than an area where the first conductive film 21 is provided. The first conductive film 21 is interposed between the first solder material 31 and the first conductive member 11.

The first peripheral region 11r of the first conductive member 11 is located around a region where the semiconductor element 40 overlaps, in the positive and negative directions of the X direction and the positive and negative directions of the Y direction. The first conductive film 21 is provided in at least a part of the first peripheral region 11r, in the positive and negative directions of the X direction and the positive and negative directions of the Y direction, respectively. However, the first conductive film 21 is separated from the first protrusions 11p.

That is, as long as the first conductive film 21 does not reach the first protrusions 11p, it is possible to form the first conductive film 21 to have a wide area protruding from the first solder material 31. In the positive direction of the X direction and the positive direction and the negative direction of the Y direction of the first conductive member, the first conductive film 21 may be formed wider than that in the case illustrated in FIG. 6.

For example, the first conductive film 21 may be formed wholly on a surface of the first peripheral region 11r except for an area in the vicinity of the first protrusions 11p. That is, the first conductive film 21 is formed through plating, for example. However, it is limited that a mask for the plating to be present in the area in the vicinity of the first protrusions 11p in the first peripheral region 11r. In other words, the mask for the plating may cover at least the first protrusions 11p. It is not necessary to form a mask in a region located in the positive direction of the X direction with respect to a predetermined position between the first protrusions 11p and the semiconductor element 40 in the X direction, making formation of a mask easier.

With the semiconductor device 102 according to the second embodiment, where the first conductive film 21 is provided to have an area wider than that in the semiconductor device 101 according to the first embodiment, it is possible to suppress resin peeling in the vicinity of the first protrusions 11p in the first peripheral region 11r, improving reliability of the semiconductor device. In addition, compared with the semiconductor device 101 according to the first embodiment, it is possible to further suppress generation of a Kirkendall void, making it possible to suppress deterioration of characteristics of the semiconductor device.

In the semiconductor device 102 illustrated in FIG. 5, the first conductive film 21 is provided wider than that in the semiconductor device 101 according to the first embodiment. However, the first conductive film 21 is not formed in the vicinity of the first protrusions 11p in the first peripheral region 11r. That is, the first conductive film 21 and the resin 50 are in contact with each other in a region close to the semiconductor element 40 even in the first peripheral region 11r. Even if resin peeling occurs, it is possible to suppress such an event that a crack grows and reaches one of the first protrusions 11p. One reason for this is that, in the vicinity of the first protrusions 11p in the first peripheral region 11r, the first peripheral region 11r and the resin 50 are in direct contact with each other, resulting in a high degree of adhesion. Occurrence of resin peeling in the vicinity of the first protrusions 11p in the first peripheral region 11r is suppressed. Ingress of moisture, for example, from outside into inside the resin 50 is suppressed.

In addition, as illustrated in FIG. 6, forming the first conductive film 21 to have an area wider than that of the first solder material 31 makes it possible to securely suppress such an event that the first conductive member 11 and the first solder material 31 are in contact with each other. Even if positional deviation of the first solder material 31 or the semiconductor element 40 occurs, the first conductive film 21 that is widely provided makes it possible to suppress such an event that the first solder material 31 is in contact with the first conductive member 11.

That is, according to the present embodiment, it is possible to more securely form the first conductive film 21 between the first conductive member 11 and the first solder material 31, instead of allowing the first conductive film 21 and the resin 50 to be in partial contact with each other. Since the first conductive film 21 makes it possible to suppress occurrence of a Kirkendall void, it is possible to further suppress deterioration of characteristics of the semiconductor device, compared with the first embodiment.

### Third Embodiment

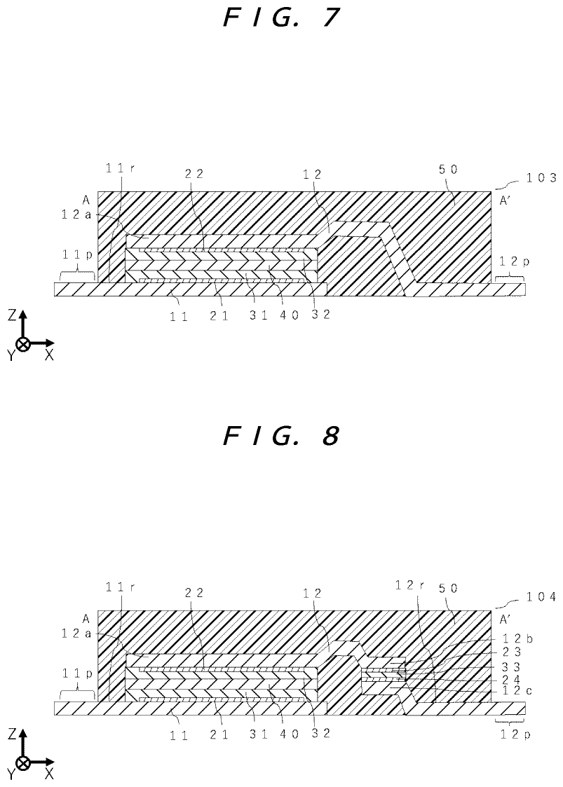

FIG. 7 is a cross-sectional view of a semiconductor device 103 according to a third embodiment. Part of description, which is common to the semiconductor device 101 according to the first embodiment, will be omitted.

A second conductive film 22 is provided in at least a part between the second solder material 32 and the first region 12a of the second conductive member 12. The second conductive film 22 is covered with the second solder material 32. In other words, the second conductive film 22 is not in contact with the resin 50.

The second conductive film 22 includes a metal element that is smaller in diffusion coefficient than a metal element forming the first region 12a of the second conductive member 12. The second solder material 32 includes, for example, a solder containing Sn. The second conductive film 22 includes, for example, a metal containing Ni. The first region 12a of the second conductive member 12 includes, for example, a metal containing Cu.

The second conductive film 22 is, for example, a film of a metal containing Ni, which is provided in at least a part between the metal containing Sn and the metal containing Cu. The second conductive film 22 functions as a barrier metal that suppresses the Kirkendall effect that occurs between the metal containing Sn and the metal containing Cu.

In addition, for a shape of the second conductive film 22, it is possible to take one of various shapes such as a square shape or an oval shape, and may be divided into a plurality of portions, similar to the cases described with reference to FIGS. 4A, 4B, and 4C.

With the semiconductor device 103 according to the present embodiment, where the second conductive film 22 is provided in at least a part between the second solder material 32 and the first region 12a, it is possible to suppress the Kirkendall effect between the second solder material 32 and the first region 12a, making it possible to suppress occurrence of a Kirkendall void in the first region 12a.

It is possible to suppress a Kirkendall void on both an upper side and a lower side of the semiconductor element 40, making it possible to suppress deterioration of characteristics of the semiconductor device 103. With the semiconductor device 103 according to the present embodiment, it is possible to further suppress generation of a Kirkendall void, making it possible to suppress deterioration of characteristics of the semiconductor device, compared with the semiconductor device 101 according to the first embodiment.

### Fourth Embodiment

a FIG. 8 is a cross-sectional view illustrating semiconductor device 104 according to a fourth embodiment. Description of those common to the semiconductor device 103 according to the third embodiment will be partially omitted.

The second conductive member 12 illustrated in FIG. 8 is different from that of the semiconductor device 103 according to the third embodiment in a structure between the first region 12a and the second protrusions 12p. The second conductive member 12 further includes, in addition to the first region 12a and the second protrusions 12p, a second region 12b, a third conductive film 23, a third solder material 33, a fourth conductive film 24, and a third region 12c.

The second region 12b is formed continuously with the first region 12a. The second region 12b includes, for example, a metal containing Cu. A portion that is different in position in the Z direction from the first region 12a and the second region 12b may be provided between the first region 12a and the second region 12b. For example, as illustrated in FIG. 8, it is located in the positive direction of the Z direction than the first region 12a and the second region 12b, making it possible to provide a structure for suppressing a short circuit failure due to the second solder material 32.

The third conductive film 23 is formed between the second region 12b and the third solder material 33. The third conductive film 23 includes, for example, a metal containing Ni, and may be formed to be identical in material to the second conductive film 22. The third conductive film 23 is formed through plating, for example.

The third solder material 33 is provided between the third conductive film 23 and the fourth conductive film 24. The third solder material 33 includes, for example, a solder containing Sn. The third solder material 33 may be formed to be identical in material to the first solder material 31 and the second solder material 32.

The fourth conductive film 24 is formed between the third solder material 33 and the third region 12c. The fourth conductive film 24 includes, for example, a metal containing Ni, and may be formed to be identical in material to the third conductive film 23.

The third region 12c is provided under the fourth conductive film 24, and is formed continuously with the second protrusions 12p, for example. It is preferable that the fourth conductive film 24 be formed in the third region 12c, while the fourth conductive film 24 be not formed on the second protrusions 12p.

A region located between the third region 12c and the second protrusions 12p is referred to as a second peripheral region 12r. Even when the third region 12c and the second protrusions 12p are integrally formed, it is desirable that the fourth conductive film 24 be selectively formed between the third solder material 33 and the third region 12c, and the fourth conductive film 24 be not provided in the second peripheral region 12r. It is possible to improve a degree of adhesion between the second conductive member 12 and the resin 50.

Note that a portion including the second protrusions 12p and the third region 12c is formed to be identical in material to the first conductive member 11, for example. An example of processes of forming the second protrusions 12p and the third region 12c will now be described herein.

A continuous single conductive member from the first protrusions 11p of the first conductive member 11 to the second protrusions 12p of the second conductive member 12 is first prepared. Next, the single conductive member is cut to obtain the first conductive member 11 illustrated in FIG. 8 as a side including the first protrusions 11p. On the other hand, a side including the second protrusions 12p further requires a process of bending the conductive member. Providing a step in the Z direction between the second protrusions 12p and the third region 12c through the process of bending the conductive member makes it possible to obtain the structure illustrated in FIG. 8.

That is, for the structure illustrated in FIG. 8, it is possible to partially and simultaneously perform the process of forming the first conductive member 11 and the process of forming a portion extending from the second protrusions 12p and reaching the third region 12c in the second conductive member 12. In the semiconductor device 103 according to the third embodiment, it has been necessary to separately prepare the second conductive member 12 that is different from the first conductive member 11. Since it is possible to use an identical material to form the first conductive member 11 and a part of the second conductive member 12, according to the present embodiment, on the other hand, it is possible to improve manufacturing efficiency.

With the semiconductor device 104 according to the present embodiment, it is possible that the second conductive member 12 includes the second region 12b and the third region 12c electrically coupled to the second region 12b by the third solder material 33. It is possible to form the member including the third region 12c to be identical in material to the first conductive member 11. Therefore, it is possible to improve manufacturing efficiency and to reduce a manufacturing cost.

In addition, the second conductive member 12 is not integrally formed. The third solder material 33 is provided between the second region 12b and the third region 12c. By forming the third conductive film 23 and the fourth conductive film 24, it is possible to suppress the Kirkendall effect between the second region 12b and the third solder material 33 and between the third region 12c and the third solder material 33.

On the other hand, it is desirable that the fourth conductive film 24 be selectively provided under the third solder material 33. By preventing the fourth conductive film 24 and the resin 50 from being in close contact with each other in the second peripheral region 12r, it is possible to improve a degree of adhesion between the second conductive member 12 and the resin 50.

With the semiconductor device 104 according to the present embodiment, it is possible to improve manufacturing efficiency of the first conductive member 11 and the second conductive member 12. It is possible to suppress generation of a Kirkendall void among the second region 12b, the third region 12c, and the third solder material 33. It is possible to reduce a risk of resin peeling in the second peripheral region 12r.

### Fifth Embodiment

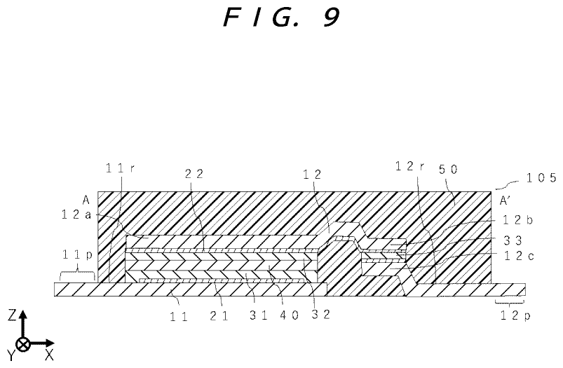

FIG. 9 is a cross-sectional view of a semiconductor device 105 according to a fifth embodiment. Description of portions common to those of the semiconductor device 104 according to the fourth embodiment will be partially omitted.

In FIG. 9, the second conductive film 22 is continuously formed from the first region 12a to the second region 12b. The second conductive film 22 includes, for example, the metal containing Ni.

FIG. 8 has been illustrated the second conductive film 22 and the third conductive film 23 as the conductive films formed separately from each other. It is possible to form a structure in which the second conductive film 22 is continuously formed from the first region 12a to the second region 12b, as illustrated in FIG. 9, on the other hand, by wholly and uniformly performing plating on a surface. Compared with a case where plating is selectively performed, similar to the semiconductor device 104 according to the fourth embodiment, formation of a mask is not necessary, making it possible to reduce a manufacturing cost.

The second conductive film 22 is provided only on a lower surface facing the second solder material 32 and the third solder material 33 in a portion including the first region 12a and the second region 12b. In other words, the second conductive member 12 is in contact with the resin 50 on an opposite surface. The second conductive member 12 includes, for example, the metal containing Cu, making it possible to increase a degree of adhesion to the resin on an upper surface.

With the semiconductor device 105 according to the present embodiment, integrally forming the second conductive film 22 extending from the first region 12a and reaching the second region 12b makes it possible to reduce a manufacturing cost.

Note that, between the first region 12a and the second region 12b, there is a portion where the second conductive film 22 and the resin 50 are in contact with each other, possibly leading to a risk of resin peeling. However, an interface between the second conductive film 22 and the resin 50 is located away from the first protrusions 11p and the second protrusions 12p in the resin 50, making it possible to reduce such a risk that a crack due to resin peeling reaches an area in the vicinity of one of the first protrusions 11p or the second protrusions 12p to allow moisture, for example, to enter from outside.

According to at least one of the embodiments described above, by forming the first conductive film 21 in at least a part between the first conductive member 11 and the first solder material 31, it is possible to suppress a Kirkendall void and to suppress deterioration of characteristics of the semiconductor device. Simultaneously, by not forming the first conductive film 21 in at least a part of the first peripheral region 11r, it is possible to suppress peeling of the resin 50, improving reliability of the semiconductor device.

The embodiments have been described above with reference to the specific examples. However, embodiments are not limited to these specific examples. That is, those obtained as those skilled in the art appropriately apply a design change to these specific examples are also included in the scope of the embodiments, as long as they present the features of the embodiments. Each component included in each of the specific examples described above and its arrangement, a material, a condition, a shape, and a size, for example, are not limited to those exemplified, and may be appropriately changed.

In addition, it is possible to combine the components included in the embodiments described above, as far as it is technically possible. Such a combination is also included in the scope of the embodiments, as long as it presents the features of the embodiments. In addition, within the scope of the idea of the embodiments, a person skilled in the art is able to conceive various modifications and corrections. It is understood that the modifications and corrections also belong to the scope of the embodiments.

Although some embodiments of the present invention have been described, these embodiments have been presented as examples, and are not intended to limit the scope of the invention. It is possible to implement these novel embodiments in various other forms. It is possible to make various omissions, substitutions, and changes without departing from the gist of the invention. These embodiments and modifications thereof are included in the scope and gist of the invention, and are included in the invention described in the claims and the equivalent scope thereof.

What is claimed is:

1. A semiconductor device comprising:
a first conductive member;
a first conductive film provided on a part of the first conductive member and including a metal element that is smaller in diffusion coefficient than the first conductive member;
a first solder material provided on the first conductive film;
a semiconductor element provided on the first solder material;
a second solder material provided on the semiconductor element;
a second conductive member including a first region facing the semiconductor element via the second solder material;
a resin sealing the first conductive member, the second conductive member, the first conductive film, the first solder material, the second solder material, and the semiconductor element; and
a first peripheral region of the first conductive member that is in contact with the resin and is located around a region where the semiconductor element overlaps.

2. The semiconductor device according to claim 1, wherein
the first conductive member includes a first protrusion exposed from the resin, and
the first peripheral region and the resin are in direct contact with each other in a vicinity of the first protrusion in the first peripheral region.

3. The semiconductor device according to claim 1, wherein
an area where the first solder material is provided is greater than an area where the first conductive film is provided.

4. The semiconductor device according to claim 1, wherein
a part of the first solder material is in direct contact with the first conductive member.

5. The semiconductor device according to claim 1, wherein
an area of where the first conductive film is provided is from 20 to 90% of an area where the first solder material is provided.

6. The semiconductor device according to claim 1, wherein
an area where the first solder material is provided is smaller than an area where the first conductive film is provided.

7. The semiconductor device according to claim 1, wherein
the first solder material and the first conductive member are not in direct contact with each other.

8. The semiconductor device according to claim 1, further comprising a second conductive film formed in at least a part between the first region and the second solder material and including a metal element that is smaller in diffusion coefficient than a metal element forming the first region.

9. The semiconductor device according to claim 8, wherein the second conductive member further includes:
a second protrusion exposed from the resin;
a second region provided between the second protrusion of the second conductive member and the first region and formed continuously with the first region, and
a third region formed continuously with the second protrusion and separated from the second region.

10. The semiconductor device according to claim 9, further comprising:
a third solder material provided between the second region and the third region and
a third conductive film provided in at least a part between the second region and the third solder material.

11. The semiconductor device according to claim 10, further comprising:
a fourth conductive film provided in at least a part between the third region and the third solder material.

12. The semiconductor device according to claim 10, wherein the second conductive film is formed continuously with the third conductive film from an area between the first region and the first solder material to an area between the second region and the third solder material.

13. The semiconductor device according to claim 12, wherein the second conductive member further includes a second peripheral region that is located between the third region and the second protrusion and is in direct contact with the resin.

14. The semiconductor device according to claim 1, wherein
the first conductive member includes a metal containing Cu,
the first conductive film is a metal containing Ni, and
the first solder material includes a metal containing Sn.

15. The semiconductor device according to claim 1, wherein the first solder material contains Sn at a mass percent concentration of 50% or more.

16. The semiconductor device according to claim 1, wherein the first solder material contains at least Pb, Sb, Ni, Ag, Bi, Cu, or Zn.

17. The semiconductor device according to claim 1, wherein
a metal-oxide semiconductor field-effect transistor (MOSFET) is formed in the semiconductor element,
the first conductive member is electrically coupled to a drain electrode of the MOSFET, and
the second conductive member is electrically coupled to a source electrode of the MOSFET.

18. A semiconductor device comprising:
a first conductive member;
a first conductive film provided on a part of the first conductive member and including a metal element that is smaller in diffusion coefficient than the first conductive member;
a first solder material provided on the first conductive film;
a semiconductor element provided on the first solder material;
a second solder material provided on the semiconductor element;
a second conductive member including a first region facing the semiconductor element via the second solder material;
wherein an area where the first solder material is provided is greater than an area where the first conductive film is provided.

19. A semiconductor device comprising:
a first conductive member;
a first solder material provided on the first conductive film;
a semiconductor element provided on the first solder material;
a second solder material provided on the semiconductor element;
a second conductive member including a first region facing the semiconductor element via the second solder material;
a first conductive film provided between the second solder material and the second conductive member and including a metal element that is smaller in diffusion coefficient than the second conductive member.

20. The semiconductor device according to claim 19, wherein
an area where the second solder material is provided is greater than an area where the first conductive film is provided.
